(19) United States
(12) Patent Application Publication
(10) Pub. No.: US 2004/0100276 A1
(43) Pub. Date: May 27, 2004

(54) Method and apparatus for calibration of a vector network analyzer

(76) Inventor: Myron Fanton, Tinley Park, IL (US)

Correspondence Address: BABCOCK IP LLC, 24154 LAKESIDE DRIVE, LAKE ZURICH, IL, 60047, US

(21) Appl. No.: 10/303,991

(22) Filed: Nov. 25, 2002

(51) Int. Cl. G01R 35/00; G01R 27/04; G01R 27/32; G01D 18/00

(52) U.S. Cl. 324/601; 702/85

(57) ABSTRACT

A method and apparatus for calibrating a vector network analyzer for use with a test system using a mathematical model of, for example, a slotted line. Voltage and displacement data sampled along the slotted line, used with the mathematical model, creates a plurality of equations which may be solved to generate a reflection coefficient which may be used as an impedance standard of known accuracy and used to calibrate a VNA thereby, without actual use of precision impedance standards.

### BACKGROUND

1. Field of the Invention

The invention generally relates to a method and apparatus for calibration of a vector network analyzer (VNA). Specifically, the invention relates to VNA calibration using, for example, a slotted line and voltage measurements taken from multiple points along the slotted line. Alternatively, a uniform transmission line may be used and the voltage measurements take from discrete points along the uniform transmission line.

2. Description of Related Art

VNAs may be used to measure the electrical characteristics of an electrical component/structure, referred to as a device under test (DUT). Measurement accuracy using a VNA is increased if the VNA is calibrated prior to use. Calibration may be performed each time the VNA is energized, exposed to environmental changes or has changes made to the test frequency(s) or test system, i.e. the associated jumpers, connectors/adapters and or couplers used to couple the DUT with the VNA.

A VNA is calibrated by identifying and quantifying systemic errors present in the test system. VNA's are generally designed for use with several different methods of calibration to account for the different forms of test system errors. Each method removes one or more of the systematic errors through vector error correction. Vector error correction may characterize the systematic errors by measuring, for example, calibration standards (devices with known s-parameters) then mathematically removing the effects of the systematic errors from subsequent measurements on the DUT.

A common method of calibration involves the alternate use of shorts, opens, loads, and a thru (direct connection of VNA test ports) using a known high precision standard in place of the DUT. This method may be time consuming and expensive, requiring a range of different standards and or adapters to approximate a range of desired DUTs. Further, each time the test system is assembled with a different standard or configuration, the interconnections between components may become worn or damaged, introducing further errors into the calibration. Also, the connections and reconnections themselves may cause erroneous calibrations due to variances in the torque, contact surface area, contact pressure and or alignment between the various connectors. In many cases, no standard similar to the DUT exists. Further, it may be impossible to connect available standards to each other, the VNA and or the DUT.

Another calibration method may include a series of test system electrical models loaded into the VNA. The test system electrical model closest to the one actually used to couple the VNA to the DUT is selected and a stored series of error factors applied. The calibration accuracy may be only as accurate as the electrical model used. For maximum accuracy, a separate electrical model may be required for every conceivable test system which might arise and errors may again occur as test system components become worn or damaged, modifying the actual electrical characteristics of the test system from those expected by the chosen model.

Other VNA calibration methods exist. Some methods are optimized for determining a single form of error systemic to a specific test system and test parameter configuration. For high precision DUT measurement, several calibration methods may be used and the resulting error factors combined. However, multiple calibration methods create additional calibration time and expense.

It is an object of the present invention to solve these and other problems that will become clear to one skilled in the art upon review of the following specification.

### BRIEF DESCRIPTION OF THE FIGURES

The accompanying drawings, which are incorporated in and constitute a part of this specification, illustrate embodiments of the invention and, together with a general description of the invention given above, and the detailed description of the embodiments given below, serve to explain the principles of the invention.

FIG. 1 is a diagram showing one embodiment of a test system according to the invention.

FIG. 2 is a flow chart showing a typical Calibration and DUT testing sequence, according to the invention.

### DETAILED DESCRIPTION

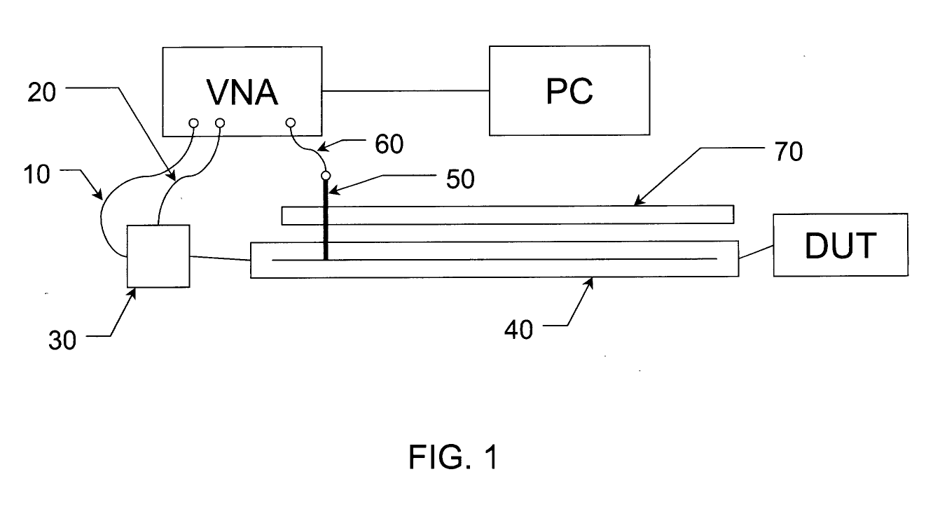

A VNA test system is shown in FIG. 1. A source signal generated by the VNA is coupled to the test system by an input jumper 10. A reflected signal is coupled from the test system back to the VNA by an output jumper 20. The input jumper 10 and output jumper 20 send and receive their respective signals through a directional coupler 30. The directional coupler 30 is coupled via any required connectors, adapters and or jumpers to a slotted line 40 that is coupled in-line with the DUT, for example an antenna. Alternatively, the directional coupler 30 may be built into the VNA, eliminating the need for input jumper 10, output jumper 20 and their associated connectors by internalizing them in a hard wired configuration within the body of the VNA. A voltage measurement probe 50, coupled to the VNA by a sample jumper 60, may be introduced at a known location along the slotted line 40 to sample the voltage. A position encoder 70 indicates the position of the voltage measurement probe 50 along the slotted line 40.

A complex voltage standing wave may be modeled as shown in equation 1:

V=Vₒ(e^{jβx}+ρe^{-jβx}) Eq. 1

In equation 1, x is a position along a conductor, β is the propagation constant, ρ is the voltage reflection coefficient and Vₒ is the source voltage magnitude.

If the standing wave is measured by applying the voltage measurement probe 50 along the slotted line 40, the measured voltage is modeled as shown in equation 2:

Vₘ=C(e^{jβx}+ρe^{-jβx})e^{-jβy Eq.} 2

In equation 2, y is the length of the coupling probe line and C is a constant representing the product of the source voltage and coupling coefficient. Phase shift in the coupling probe may be incorporated into the βy term.

Multiple equations, generated by taking voltage measurement probe 50 samples at N different positions (x₁, x₂, . . . , x_{N}) along the slotted line 40 at a common frequency, may be described in matrix form by equation 3:

$$\{ \begin{matrix}{V}_{m 1} \\ {V}_{m 2} \\ ⋮ \\ {V}_{mN}\end{matrix} \} = [ \begin{matrix}{ⅇ}^{j β {x}_{1}} & {ⅇ}^{- j β {x}_{1}} \\ {ⅇ}^{j β {x}_{2}} & {ⅇ}^{- j β {x}_{2}} \\ ⋮ & ⋮ \\ {ⅇ}^{j β {x}_{N}} & {ⅇ}^{- j β {x}_{N}}\end{matrix} ] \{ \begin{matrix}C {ⅇ}^{- j β y} \\ ρ C {ⅇ}^{- j β y}\end{matrix} \} \qquad Eq . 3$$

As the slotted line 40 sample voltage measurements are made, some errors are introduced, which may be modeled as shown in equation 4:

$$\{ \begin{matrix}{ϵ}_{1} \\ {ϵ}_{2} \\ ⋮ \\ {ϵ}_{N}\end{matrix} \} = [ \begin{matrix}{ⅇ}^{j β {x}_{1}} & {ⅇ}^{- j β {x}_{1}} \\ {ⅇ}^{j β {x}_{2}} & {ⅇ}^{- j β {x}_{2}} \\ ⋮ & ⋮ \\ {ⅇ}^{j β {x}_{N}} & {ⅇ}^{- j β {x}_{N}}\end{matrix} ] \{ \begin{matrix}C {ⅇ}^{- j β y} \\ ρ C {ⅇ}^{- j β y}\end{matrix} \} - \{ \begin{matrix}{V}_{m 1} \\ {V}_{m 2} \\ ⋮ \\ {V}_{mN}\end{matrix} \} \qquad Eq . 4$$

In matrix notation, equation 4 may be written as shown in equation 5.

\tilde{ε}=\overline{B}\tilde{p}−\tilde{α} Eq. 5

Using parameter estimation, the error may be minimized by selecting for \tilde{p} the parameter vector \hat{p} that is the solution to the following complex matrix equation 6:

\overline{B}^{*T}\overline{B}\hat{p}=\overline{B}^{*T}\tilde{α} Eq. 6

The parameter vector \hat{p} contains the best estimate of the voltage reflection coefficient of the load. Error statistics, for example the variance, may be computed to indicate how well the set of measurements fit the analytical model (equation 2). For higher accuracy, equation 2 may be enhanced to include known systematic errors in the slotted line. Similar error minimization techniques may be employed to produce the best estimate of the reflection coefficient.

The reflection coefficient obtained through this method may be considered an impedance standard of known accuracy. One skilled in the art will recognize that this impedance standard may be used in the various error correction/calibration schemes of a VNA.

For example, the “Response” calibration technique models the VNA system as a complex proportionality constant (the calibration coefficient) as shown in equation 7:

ρ_{c}=Aρₘ Eq. 7

In equation 7, ρ_{c} is the calibrated reflection coefficient and ρₘ is the measured reflection coefficient. During calibration, the impedance standard provides a known reflection coefficient. Equation 7 may then be easily solved for the calibration coefficient. More elaborate calibration routines may require multiple impedance standard measurements, which may be acquired by making multiple slotted line 40 measurements and processing the data as described above.

The required calculations/data manipulation may be performed manually or various levels of computer processing may be utilized. The VNA may have embedded data processing circuits and a numeric processor. Alternatively, the VNA may be coupled with an external processor, for example a personal computer (PC) or other well known computing means. Data acquisition/transfer links between the selected computing means, the VNA and or the position encoder 70 may be used to minimize requirements for manual data translation between the devices.

The position encoder 70 may range in complexity from a simple series of graduated markings along the slotted line 40 to an electromechanical or optical position sensor or a plurality of hardwired switches each coupled to discrete, fixed probes, coupled directly to the, for example, PC.

The slotted line 40 may be, for example, a coaxial conductor with a slot or a series of spaced apart apertures through which the voltage measurement probe 50 may be inserted to contact the center conductor of the coaxial cable. Alternatively, the voltage measurement probe 50 may be a series of switches each coupled to discrete, fixed probes, coupled by a common sample jumper 60 to the VNA, the switches controlled by the PC and known systemic errors caused by the different switches added depending upon the switch in use, to enable an automated VNA calibration test system.

Any electrical disturbances, for example connectors between the DUT and the slotted line 40 will not be captured by measurements upon the slotted line 40. These disturbances may be estimated and added to the calculation manually or the electrical model enhanced to include these effects. Alternatively, the slotted line 40 may be formed with a direct lead to the DUT, minimizing systemic errors that are not accounted for in the calibration. For example, the slotted line may be formed in a section of antenna mast. In this embodiment, the device under test may be an antenna or antenna element, for example a radiating slot or radiator element. Errors due to connector wear and improper connector assembly may be reduced by attaching the directional coupler 30 directly to the slotted line 40, thereby removing one set of connectors and their associated systemic errors.

In a micro circuit embodiment, the slotted line 40 may be formed in a, for example CMOS, integrated circuit with different voltage measurement probe 50 sample points switchable by semiconductor based switches coupled to fixed probes, and taken off to an array of leads from the CMOS package. In this form, measurements upon a micro circuit and or micro strip antenna may be made without requiring the insertion of circuit testing clips/jumpers and their associated systemic errors, in-line. In the analysis of an integrated circuit, it may be impossible to attach standards. However, by the method described above, fixed probes may be integrated into the design of the integrated circuit to enable circuit analysis according to the invention.

In other embodiments, the slotted line 40 may be replaced with other structures providing independent measurements of complex voltage standing wave ratios and or complex reflection coefficients. Multiple measurements generating a plurality of equations solvable for the, for example, reflection coefficient as described above.

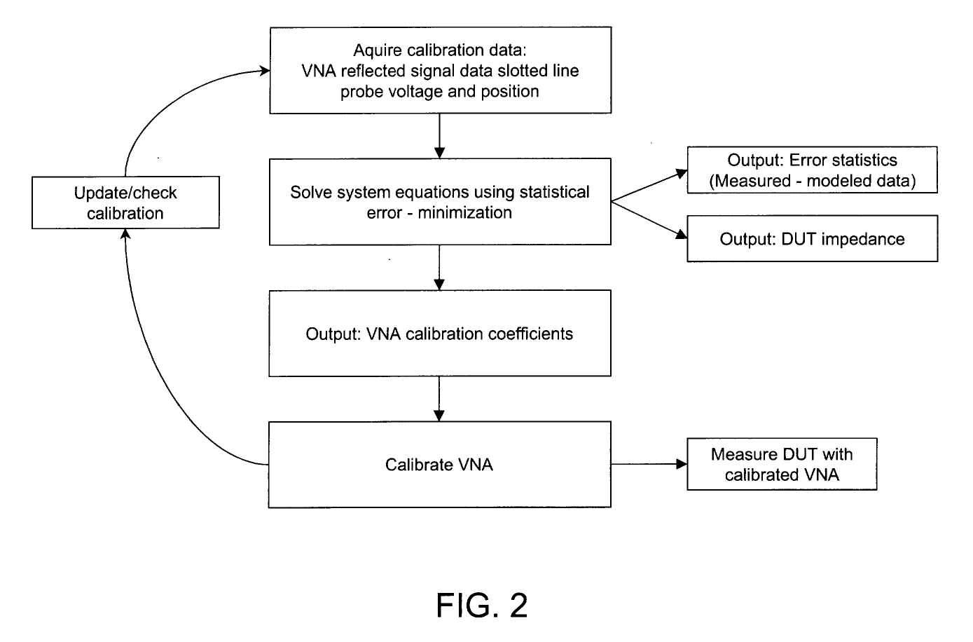

The measurements and data processing described herein may be used as part of a calibration method as shown in FIG. 2. Calibration data acquisition and processing, calibration coefficient generation, error statistical handling, DUT impedance generation and VNA calibration coefficient generation may be used to calibrate the VNA. The calibrated VNA being regularly checked and updated as necessary to ensure that the DUT measurements obtained from the calibrated VNA are as accurate as possible.

As decribed, the invention provides a reflection calibration method using a simplified test apparatus that does not use the previously required series of precision impedance standards and repeated modifications to the test system interconnections. If desired, the calibration calculations may be fully automated by the use of a position encoder 70 which cooperates with the VNA to feed test system slotted line 40 voltage measurement and position data to a processor which may be external or internal to the VNA.

Table of Parts

| | |
|---|---|
| 10 | input jumper |
| 20 | output jumper |
| 30 | directional coupler |
| 40 | slotted line |
| 50 | voltage measurement probe |
| 60 | sample jumper |
| 70 | position encoder |

Where in the foregoing description reference has been made to ratios, integers, components or modules having known equivalents then such equivalents are herein incorporated as if individually set forth.

While the present invention has been illustrated by the description of the embodiments thereof, and while the embodiments have been described in considerable detail, it is not the intention of the applicant to restrict or in any way limit the scope of the appended claims to such detail. Additional advantages and modifications will readily appear to those skilled in the art. Therefore, the invention in its broader aspects is not limited to the specific details, representative apparatus, methods, and illustrative examples shown and described. Accordingly, departures may be made from such details without departure from the spirit or scope of applicant's general inventive concept. Further, it is to be appreciated that improvements and/or modifications may be made thereto without departing from the scope or spirit of the present invention as defined by the following claims.

We claim:

1. A method of using a test system for calibrating a vector network analyzer, comprising the steps of:
obtaining a data set including a source signal, a reflected signal, a voltage and a voltage measurement position within the test system;
applying a plurality of complex voltage standing wave models representative of the test system to the data set;
solving the plurality of complex voltage standing wave models for a representative voltage reflection coefficient;
applying the representative voltage reflection coefficient to the vector network analyzer as an impedance standard of known accuracy to calibrate the vector network analyzer.

2. The method of claim 1, wherein the data set is obtained via a test system including a slotted line from which the voltage and the voltage measurement position is obtained.

3. The method of claim 1, wherein the plurality of complex voltage standing wave models are solved using a software program run on a processor.

4. The method of claim 3, wherein the processor is internal to the vector network analyzer.

5. The method of claim 3, wherein the processor is a personal computer.

6. The method of claim 3, wherein a position encoder transmits the voltage measurement position data to the processor.

7. The method of claim 1, further including the step of performing statistical analysis on the plurality of complex voltage standing wave models to generate an error correction coefficient.

8. A test system for calibrating a vector network analyzer having source signal, reflected signal and voltage measurement ports, comprising:
a directional coupler, the directional coupler connectable to the source signal and reflected signal ports of the vector network analyzer and a first end of
a slotted line, a second end of the slotted line connectable to a device under test; and
a voltage measurement probe connectable to the voltage measurement port of the vector network analyzer and operable to measure a voltage along the slotted line.

9. The test system of claim 8 further including a position encoder configurable to measure the position of the voltage measurement probe.

10. The test system of claim 9, wherein the position encoder transmits position data to a processor.

11. The test system of claim 8 further including a processor.

12. The test system of claim 8 wherein the processor is a personal computer.

13. The test system of claim 8 wherein the processor is internal to the vector network analyzer.

14. The test system of claim 8 wherein the slotted line is formed on an integrated circuit.

15. The test system of claim 14 wherein a plurality of measurement points are provided along the slotted line connectable to the slotted line by a plurality of semiconductor switches.

16. The test system of claim 8 wherein the slotted line is formed in a portion of antenna mast.

17. The test system of claim 16 wherein the device under test is an antenna.

18. The test system of claim 8 wherein the directional coupler is directly attached to the first end of the slotted line.

19. The test system of claim 8 wherein the directional coupler is located within the vector network analyzer.

20. A method of calibrating a vector network analyzer for use with a test system, comprising the steps of:
creating a mathematical model of the test system;
acquiring calibration data including voltage and position measurements from a plurality of locations within the test system;
solving the mathematical model, using the calibration data, for a calibration coefficient;
applying the calibration coefficient to a calibration routine of the vector network analyzer.
